(19) United States
(12) Patent Application Publication
(10) Pub. No.: US 2003/0059721 A1
(43) Pub. Date: Mar. 27, 2003

(54) Fabrication method of semiconductor

(76) Inventors: Wen-Lo Shieh, Taipei (TW); Ning Huang, Taipei (TW); Hui-Pin Chen, Taipei (TW); Hua-Wen Chiang, Taipei (TW); Chung-Ming Chang, Taipei (TW); Feng-Chang Tu, Taipei (TW); Fu-Yu Huang, Taipei (TW); Hsuan-Jui Chang, Taipei (TW); Chia-Chieh Hu, Taipei (TW); Wen-Long Leu, Taipei (TW)

Correspondence Address: Wen-Lo Shieh, PO Box 82-144, TAIPEI, TW

(21) Appl. No.: 10/156,120

(22) Filed: May 29, 2002

(30) Foreign Application Priority Data
Sep. 26, 2001 (TW) 090123853

(51) Int. Cl. G03F 7/00

(52) U.S. Cl. 430/311; 430/313; 430/314; 430/330

(57) ABSTRACT

A fabrication method of semiconductor packaging and the packaging element is disclosed. A layer of copper is formed on a thick heat-resistant tape and the surface of the copper layer is coated with a light sensitive photoresist. A light source passes through a pre-fabricated circuit negative being performed on the copper layer such that the photoresist is retained on the surface of the copper layer. An etching step is performed so as to obtain a copper wire with circuit diagram. After that, a wire bonding or a flip chip method is used to bind copper wire circuit with the chip. An appropriate packaging method is performed, a packaging element is obtained after the heat-resistant tape is removed.

### BACKGROUND OF THE INVENTION

(a) Field of the Invention

The present invention relates semiconductor packaging, and in particular, a method of fabrication of packaging element.

(b) Description of the Prior Art

Conventional type of packaging method in obtaining thin size packaging is by means of metallic lead frame. As shown in FIG. 1, there is shown a top view of a metallic lead frame 1′. Due to the fact that the fabrication of IC metallic lead frame 1′ requires high precision punching molds and high precision fabrication tool; the cost of packaging fabrication is high. FIG. 2 shows a sectional view of a wire-bonding package of a conventional metallic lead frame.

In conventional semiconductor packaging, the chips are adhered onto the metallic lead frame′. After that gold wire 3′ is used to connect an aluminum pad 22′ of the chip 2′ and the lead connection pin 13′ of the metallic lead frame 1′. In packaging by employing metallic lead frame 1′, a chip carrier board is needed so as to adhere the exposed chip 2′. Thus, the height of the chip 2′ is protruded and the thickness is increased. After the completion of the general metallic lead frame 1′, the chip 2′ is adhered onto the chip carrier board 11′ and is totally covered by the packaging body of the epoxy resin 4′ and heat dissipation is thus difficult. Further, the metallic lead frame 1′ is an alloy made from metal (iron, nickel and copper) and its density will not be too high.

Accordingly, it is an object of the present invention to provide a fabrication method of semiconductor packaging and the packaging element which mitigates the above drawbacks.

### SUMMARY OF THE INVENTION

Accordingly, it is an object of the present invention to provide a fabrication method of semiconductor packaging and the packaging element, wherein the removal of the heat-resistant tape from the chip provides efficient heat dissipation to the chip.

Yet another object of the present invention is to provide a fabrication method of semiconductor packaging and the packaging element, wherein a heat-resistant tape is used as substrate and general method of forming circuit is employed which lowers the cost of metallic lead. Further, the direct mounting of heat-resistant tape onto the chip will reduce the removal of the bonding adhesive from the chip.

An aspect of the present invention is to provide a fabrication method of semiconductor packaging comprising the steps of providing a heat-resistant tape as substrate; forming a circuit layout on the substrate and performing a bonding with chip; forming into packaging; and removing the heat-resistant tape to form a packaging element.

The foregoing object and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a top view of a conventional metallic lead frame.

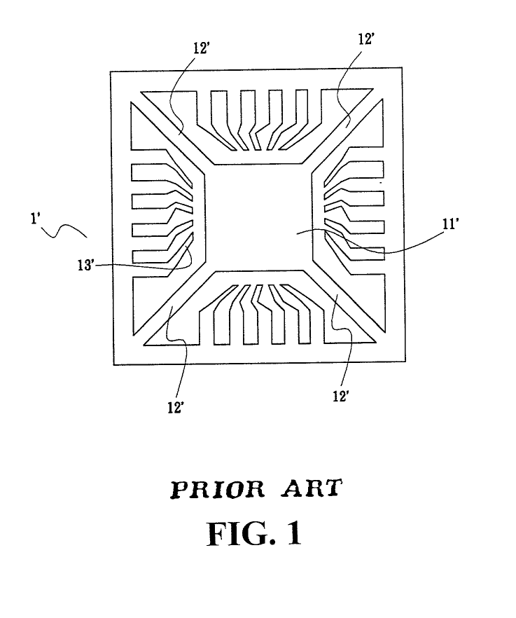

FIG. 2 is a sectional view of a wire-bonding package of a conventional metallic lead frame.

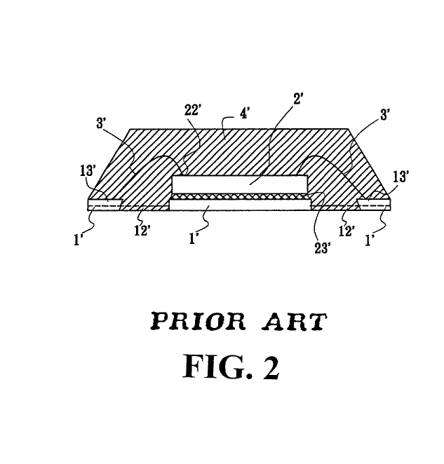

FIG. 3 is a top view of a circuit layout of a wire bonding of the present invention.

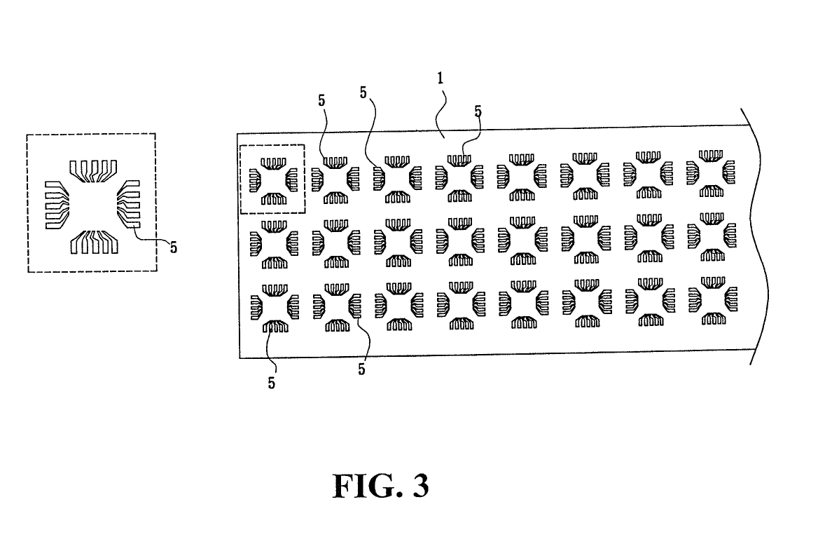

FIGS. 4A-4G schematically show the fabrication of the wire bonding in accordance with the present invention.

FIGS. 5A-5G schematically show the fabrication of the flip chip in accordance with the present invention.

FIGS. 6A and 6B show a comparison of packaging element obtained by way of flip chip bonding of the present invention and that obtained by way of conventional metallic lead frame.

### DETAILED DESCRIPTION OF THE PRESENT INVENTION

For the purpose of promoting an understanding of the principles of the invention, reference will now be made to the embodiment illustrated in the drawings. Specific language will be used to describe same. It will, nevertheless, be understood that no limitation of the scope of the invention is thereby intended, alterations and further modifications in the illustrated device, and further applications of the principles of the invention as illustrated herein being contemplated as would normally occur to one skilled in the art to which the invention relates.

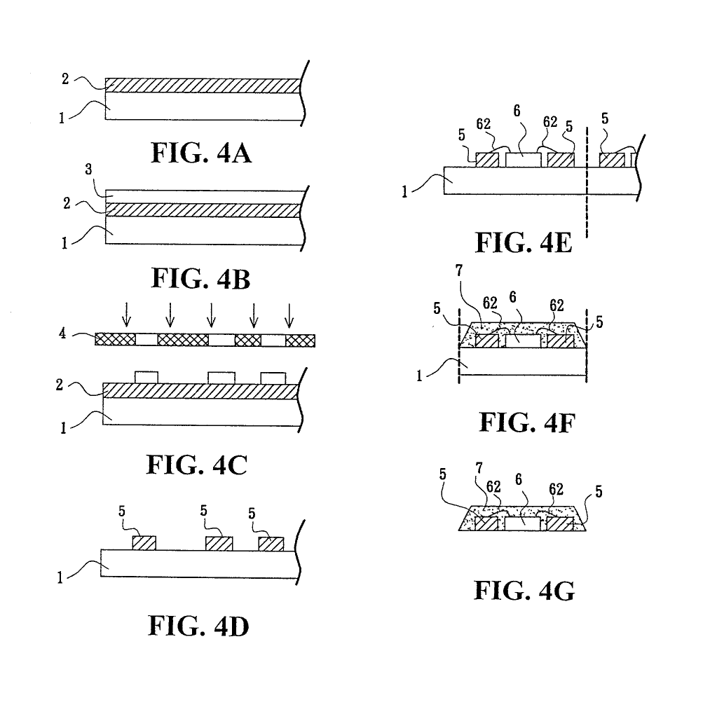

FIGS. 4A to 4G show a fabrication method of semiconductor packaging and the packaging element, wherein a heat-resistant tape is used as substrate and the surface of the substrate is formed into circuit layout. After electrically bonding with chip, a packaging is formed. By removing the heat-resistant tape from the chip, a packaging element is obtained.

In accordance with the present invention, the fabrication of chip bonding by means of wire bonding comprises the steps of

(a) forming a copper layer 2 on a heat-resistant tape 1, facilitating the making of copper wire circuit 5 (as shown in FIG. 4A);

(b) forming a photoresist layer 3 onto the copper layer 2 (as shown in FIG. 4B);

(c) exposing to form image by introducing a light source onto the photoresist 3 having a designed circuit diagram negative film; screen board 4, the pattern of the circuit portion being retained by the photoresist 3 (as shown in FIG. 4C);

(d) performing an etching step to remove the unwanted wire circuit of the copper layer 2 and cleaning the photoresist 3 to form copper wire circuit (as shown in FIG. 4D);

(e) adhering naked chip 6 onto the pre-fabricated space on the copper wire circuit 5 (on the heat-resistant tapes) and performing a wire bonding step to electrically bond the chip 6 and the copper wire circuit 5 (as shown in FIG. 4E);

(f) packaging with epoxy-resin 7 and cutting into particulate packaging bodies (as shown in FIG. 4F); and

(g) removing the heat-resistant tape 1 and the packaging to form a packaging element (as shown in FIG. 4G).

In the present preferred embodiment, the chip 6 is directly adhered onto a heat-resistant tape 1 and is then removed, thus, it is more effective as compared to wire bonding packaging of the conventional metallic lead frame 1′ to reduce the height of the packaging. Further, the rear face of the packaged chip is exposed and is excellent for heat dissipation, and the cost of the material in metallic lead frame 1′ and chip bonding glue 23′ is saved.

In accordance with the present invention, another fabrication of packaging by means of flip chip bonding comprising the steps of

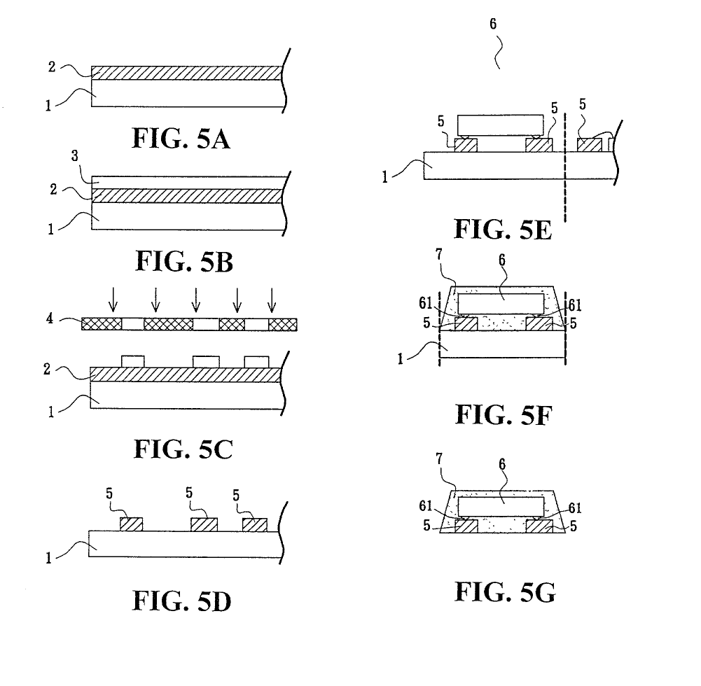

(a) forming a copper layer 2 on a heat-resistant tape 1, facilitating the making of copper wire circuit 5 (as shown in FIG. 5A);

(b) forming a photoresist layer 3 onto the copper layer 2 (as shown in FIG. 5B);

(c) exposing to form image by introducing a light source onto the photoresist 3 having a designed circuit diagram negative film; screen board 4, the pattern of the circuit portion being retained by the photoresist 3 (as shown in FIG. 5C);

(d) performing an etching step to remove the unwanted wire circuit of the copper layer 2 and cleaning the photoresist 3 to form copper wire circuit (as shown in FIG. 5C);

(e) adhering naked chip 6 onto the pre-fabricated space on the copper wire circuit 5 (on the heat-resistant tapes) and performing a wire bonding step to electrically bond the chip 6 and the copper wire circuit 5 (as shown in FIG. 5E);

(f) packaging with epoxy-resin 7 and cutting into particulate packaging bodies (as shown in FIG. 5F); and

(g) removing the heat-resistant tape 1 and the packaging to form a packaging element (as shown in FIG. 5G).

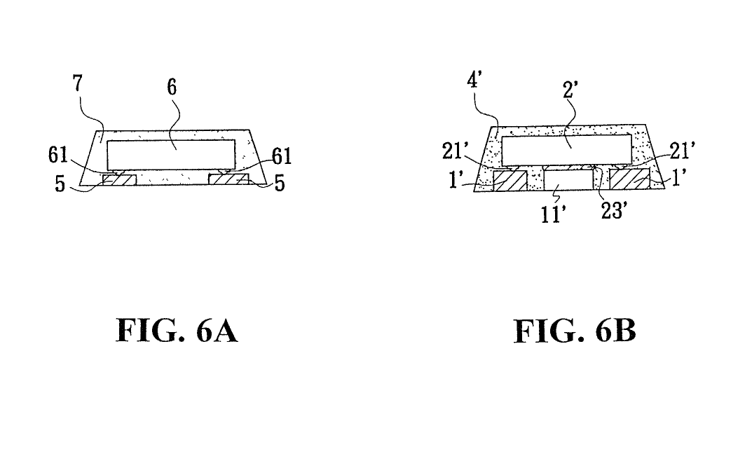

In view of the above, a chip carrier board 11′ beneath the chip is not needed and cost of material is saved as compared to the wire bonding packaging of the conventional metallic lead frame 1′ and the chip bonding glue 23′ (see FIGS. 6A and 6B).

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

We claim:

1. A fabrication method of semiconductor packaging comprising the steps of:
(a) providing a heat-resistant tape as substrate;
(b) forming a circuit layout on the substrate and performing a bonding with chip;
(c) forming into packaging; and
(d) removing the heat-resistant tape to form a packaging element.

2. The method of claim 1, wherein the step of bonding is by way of wire bonding, and a pre-fabricated space is provided on the circuit layout to accommodate the chip.

3. A fabrication method of semiconductor packaging comprising the steps of:
(a) forming a copper layer on a heat-resistant tape;
(b) forming a photoresist layer onto the copper layer;
(c) exposing to form image by introducing a light source onto the photoresist having a designed circuit diagram negative film;
(d) etching of the photoresist to form copper wire circuit;
(e) adhering naked chip onto the pre-fabricated space on the copper wire circuit and performing a wire bonding step to electrically bond the chip and the copper wire circuit;
(f) packaging with epoxy-resin and cutting into particulate packaging bodies; and
(g) removing the heat-resistant tape of the packaging to form a packaging element.

4. The fabrication method of claim 1, wherein the bonding of the heat-resistant tape with the chip is by way of flip chip method and the comprises the steps of:
(a) forming a copper layer on a heat-resistant tape;
(b) forming a photoresist layer onto the copper layer;
(c) exposing to form image by introducing a light source onto the photoresist having a designed circuit diagram negative film;
(d) etching of the photoresist to form copper wire circuit;
(e) adhering naked chip onto the pre-fabricated space on the copper wire circuit and performing a wire bonding step to electrically bond the chip and the copper wire circuit;
(f) packaging with epoxy-resin and cutting into particulate packaging bodies; and
(g) removing the heat-resistant tape of the packaging to form a packaging element.
